(19) United States
(12) Patent Application Publication
(10) Pub. No.: US 2025/0078742 A1
(43) Pub. Date: Mar. 6, 2025

(54) DISPLAY MODULE AND CONTROL METHOD THEREFOR, AND ELECTRONIC DEVICE

(71) Applicant: KunShan Go-Visionox Opto-Electronics Co., Ltd., Kunshan (CN)

(72) Inventor: Feng CHEN, Kunshan (CN)

(73) Assignee: KunShan Go-Visionox Opto-Electronics Co., Ltd., Kunshan (CN)

(21) Appl. No.: 18/949,420

(22) Filed: Nov. 15, 2024

(30) Foreign Application Priority Data
Dec. 20, 2023 (CN) 202311764506.5

(51) Int. Cl. G09G 3/3225

(52) U.S. Cl. CPC G09G 3/3225; G09G 2300/0408; G09G 2310/0278; G09G 2320/0242; G09G 2320/0686; G09G 2330/023; G09G 2354/00; G09G 2360/144

(57) ABSTRACT

Disclosed are a display module and a manufacturing method therefor, and an electronic device. The display module includes a display driver integrated circuit and a display panel. The display panel includes: an array substrate; and a plurality of isolation structures located on a side of the array substrate. The isolation structure is conductive. The plurality of isolation structures are divided into at least two groups. The display driver integrated circuit is connected to each group of the isolation structures respectively, and the display driver integrated circuit is configured to provide independent common voltage for each group of the isolation structures based on a display brightness value command received. The display driver integrated circuit provides independent common voltage for different groups of the sub-pixels. Thus, the common voltage may be configured more flexibly for the sub-pixels of different materials, thereby reducing overall energy consumption of the display module.

### CROSS-REFERENCE TO RELATED APPLICATIONS

This application claims priority to Chinese Patent Application No. 202311764506.5, filed on Dec. 20, 2023, which is hereby incorporated by reference in its entirety.

### TECHNICAL FIELD

Embodiments of the present disclosure relate to the field of display technologies, and in particular, to a display module, a control method for a display module, and an electronic device.

### BACKGROUND

As for an organic light-emitting diode (OLED) display panel, a power supply scheme that all sub-pixels share a cathode (ELVSS) is adopted. To ensure a good display effect, a voltage configuration of the cathode (ELVSS) need to follow a higher-value rule, thus increasing the power consumption of the display panel to a certain extent.

### SUMMARY

To overcome the shortcomings mentioned above, the present disclosure aims to provide a display module. The display module includes: a display driver integrated circuit and a display panel. The display panel includes: an array substrate; and a plurality of isolation structures located on a side of the array substrate. the isolation structure is conductive. The plurality of isolation structures are divided into at least two groups. The isolation structures in a same group are electrically connected to each other, and the isolation structures in different groups are electrically isolated from each other. The display driver integrated circuit is connected to each group of the isolation structures respectively, and the display driver integrated circuit is configured to provide independent common voltage for each group of the isolation structures based on a display brightness value command received.

The present disclosure further provides a control method for a display module, applied to a display module according to the present disclosure. The method includes: acquiring a display brightness value command; determining at least two common voltage values based on the display brightness value command; and generating, based on the at least two common voltage values, at least two independent common voltages, and providing the at least two independent common voltages to isolation structures of different groups in the display module respectively.

The present disclosure further provides a display module, and the display module includes a display driver integrated circuit and a display panel. The display panel includes: an array substrate; and plurality of pixel units located on a side of the array substrate. The plurality of pixel units are divided into at least two groups. The display driver integrated circuit is connected to each group of the pixel units, and the display driver integrated circuit is configured to provide independent common voltage for each group of the pixel units based on a display brightness value command received.

The present disclosure further provides an electronic device, and the electronic device includes a display panel according to the present disclosure.

Compared to a related art, the present disclosure has the following beneficial effects.

According to the display module, the control method for a display module, and the electronic device provided by the present disclosure, in a case where the common electrode of each sub-pixel is independent by setting isolation structures, the display driver integrated circuit provides independent common voltage for different groups of the sub-pixels. Thus, the common voltage may be configured more flexibly for the sub-pixels of different materials, thereby reducing overall energy consumption of the display module.

### BRIEF DESCRIPTION OF THE DRAWINGS

FIG. 1 is a sectional schematic diagram of a display panel according to an embodiment of the present disclosure.

FIG. 2 is a sectional schematic diagram of a display panel according to another embodiment of the present disclosure.

FIG. 3 is a schematic diagram of a grouping connection of the display panel according to an embodiment of the present disclosure.

FIG. 4 is a sectional schematic diagram of a display panel according to still another embodiment of the present disclosure.

FIG. 5 is a sectional schematic diagram of a display panel according to yet another embodiment of the present disclosure.

FIG. 6 is a sectional schematic diagram of a display panel according to yet another embodiment of the present disclosure.

FIG. 7 is a schematic diagram of a circuit structure of a display panel according to an embodiment of the present disclosure.

FIG. 8 is a schematic diagram of a circuit structure of a display panel according to another embodiment of the present disclosure.

FIG. 9 is a schematic diagram of a mapping correspondence record of a brightness control module according to an embodiment of the present disclosure.

FIG. 10 is a schematic diagram of a circuit structure of a display panel according to still another embodiment of the present disclosure.

FIG. 11 is a schematic diagram of a circuit structure of a display panel according to yet another embodiment of the present disclosure.

FIG. 12 is a schematic diagram of a circuit structure of a display panel according to yet another embodiment of the present disclosure.

FIG. 13 is a flowchart of a control method for a display module according to an embodiment of the present disclosure.

FIG. 14 is a flowchart of a control method for a display module according to another embodiment of the present disclosure.

FIG. 15 is a flowchart of a control method for a display module according to still another embodiment of the present disclosure.

### DETAILED DESCRIPTION OF THE EMBODIMENTS

It has been found by the inventor that in the related art, as for an OLED display module, anodes of each sub-pixel are usually connected to different pixel driving circuits in an array substrate. Therefore, the sub-pixels are provided with a driving voltage (ELVDD) independently. However, a cathode of each sub-pixel is usually a transparent electrode that is continuously connected across the entire surface, that is, the cathodes of all sub-pixel are connected to a common voltage (ELVSS). In this case, some sub-pixels require different voltages due to the different materials of their light-emitting material layers. To ensure a good display effect of all sub-pixels, the cathode voltage needs to follow a higher-value rule, thereby increasing energy consumption of the display panel to a certain extent. Patents including No. PCT/CN2023/134518, No. 202310759370.2, No. 202310740412.8, No. 202310707209.0, and No. 202311346196.5 record relevant technical solutions of the isolation structure, and their contents are incorporated herein by reference into the present disclosure for reference.

In view of this, the present embodiment provides a scheme to reduce the power consumption of the display panel. A detailed explanation of the scheme provided by the present embodiment will be provided in the following.

The present embodiment provides a display module, and the display module includes a display driver integrated circuit (DDIC) and a display panel.

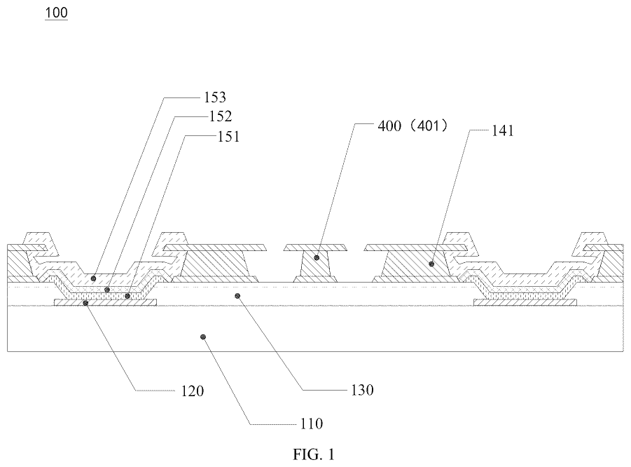

Referring to FIG. 1, the display panel 100 includes an array substrate 110 and a plurality of isolation structures 141 located on a side of the array substrate 110.

The array substrate 110 may include several film layer structures, such as a substrate, a buffer layer, an active layer, a plurality of metal layers, a plurality of insulation layers, and a planarization layer. A plurality of thin film transistors (TFT) are formed by the several film layer structures of the array substrate 110 at different positions of the array substrate 110. The TFTs may cooperate to form a plurality of pixel driving circuits used for driving pixels to emit light.

A plurality of isolation openings are formed in the isolation structure 141. The isolation structure 141 is conductive. The plurality of isolation structures are divided into at least two groups, and the isolation structures in different groups are electrically isolated from each other.

Referring back to FIG. 1, in a possible implementation, the display panel 100 provided by the present embodiment may further include a pixel defining layer 130.

The pixel defining layer 130 is located between the array substrate 110 and the plurality of isolation structures 141. The pixel defining layer includes a plurality of pixel openings, and a isolation opening is formed in the isolation structure 141. An orthographic projection of the pixel opening on the array substrate is within an orthographic projection of the isolation opening on the array substrate.

Referring back to FIG. 1, in a possible implementation, the display panel 100 provided by the present embodiment may further include a first electrode 120, a light-emitting material layer 151 and a second electrode 152.

The first electrode 120 is located on a side of the array substrate 110, where the pixel defining layer 130 is disposed, and the pixel opening of the pixel defining layer exposes the first electrode 120. Adjacent first electrodes 120 are isolated from each other by the pixel defining layer 130.

A plurality of first electrodes are disposed with intervals, and respectively connected to a pixel driving circuit in the array substrate 110.

The light-emitting material layer 151 and at least a part of the second electrode 152 are located within the pixel opening, and are sequentially stacked along a direction away from the array substrate 110. The light-emitting material layer 151 is in electrical contact with the first electrode 120, and the light-emitting material layer 151 is located between the first electrode 120 and the second electrode 152.

In this embodiment, the isolation structure 141 is configured to disconnect the light-emitting material layer 151 and the second electrode 152 located in adjacent pixel openings during formation of the light-emitting material layer 151 and the second electrode 152 of the display panel 100 through whole layer evaporation, so that the light-emitting material layers 151 and the second electrodes 152 of sub-pixels of different colors may be formed through the method of multiple whole layer evaporation and selective etching during preparation of the display panel 100. In this case, according to the display module provided be the embodiment, the second electrodes 152 corresponding to adjacent sub-pixels are disconnected at the isolation structure 141 and not directly electrically connected.

The isolation structure 141 is conductive. At least a part of the second electrode 152 extends from the pixel opening to a side, away from the array substrate 110, of the pixel defining layer 130, and is in electrical contact with the isolation structure 141.

In this embodiment, the first electrode 120 may be provided with a driving voltage (ELVDD) from the pixel driving circuit, and the second electrode 152 may be provided with a common voltage (ELVSS) from the display driver integrated circuit 200. Therefore, the light-emitting material layer 151 is driven to emit light when an electric potential difference exists between the first electrode 120 and the second electrode 152.

Optionally, the display panel 100 further includes a first inorganic encapsulation layer 153 located on a side, away from the array substrate 110, of the second electrode 152. For example, at least a part of the first inorganic encapsulation layer 153 extends, along a sidewall of the isolation structure 141 facing the isolation opening, from an inner edge of the pixel opening to a side, away from the array substrate 110, of the isolation structure 141.

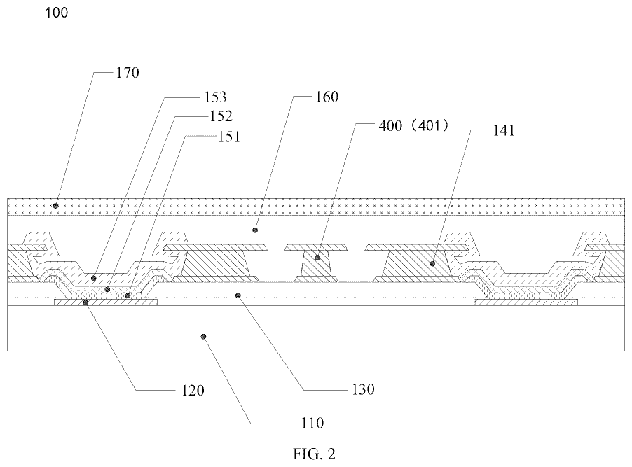

Furthermore, referring to FIG. 2, the display panel 10 may further include an organic encapsulation layer 160 located on a side, away from the array substrate 110, of the first inorganic encapsulation layer 153, and a second inorganic encapsulation layer 170 located on a side, away from the array substrate 110, of the organic encapsulation layer 160. The first inorganic encapsulation layer 153 and the second inorganic encapsulation layer 170 may be formed through chemical vapor deposition, and the organic encapsulation layer 160 may be formed by inkjet printing.

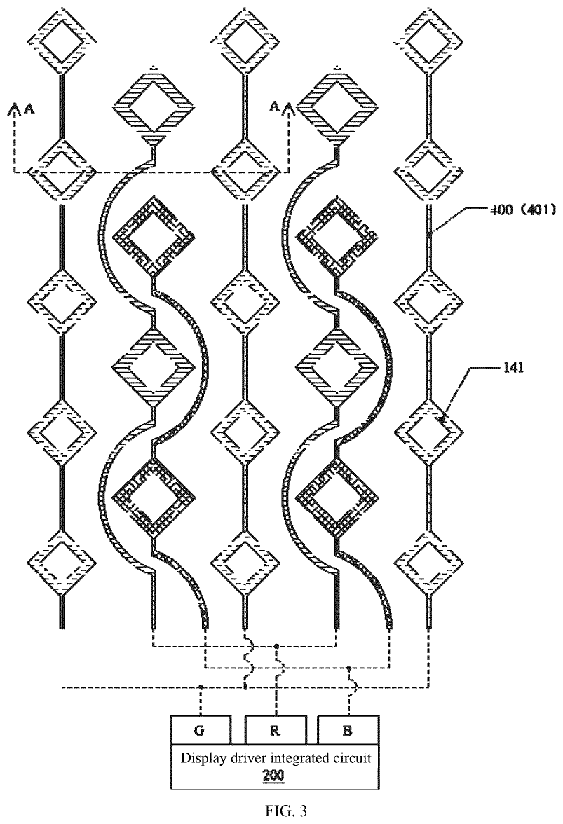

Referring to FIG. 3, the display driver integrated circuit 200 is respectively connected to each group of the isolation structures 141, and the display driver integrated circuit 200 is configured to provide independent common voltage for each group of the isolation structures 141 based on a display brightness value command received.

For example, the isolation structures 141 may be disposed with intervals, and there is a gap between adjacent isolation structures 141. The isolation structures 141 in a same group may be connected to each other through a connection wire. The isolation structures 141 in the same group may be connected into an independent common voltage supply circuit and independently connected to the display driver integrated circuit 200 through the connection wire, so that the display driver integrated circuit 200 may provide an independent common voltage for each group of the isolation structures 141. In this embodiment, common voltages provided by different groups of the isolation structures 141 may be the same or different.

Specifically, the display driver integrated circuit 200 may receive a display brightness value command. The display brightness value command may include a command generated by other application control modules that indicates a display brightness value (DBV). Then, the display driver integrated circuit 200 may independently provide at least two sets of common voltages to different groups of the isolation structures 141 respectively based on the display brightness value command. Therefore, the second electrodes 152 of different groups may be provided with independent common voltages from the isolation structures 141 of different groups.

Based on the design mentioned above, according to the display module provided by the embodiment, in a case where the second electrode 152 of each sub-pixel is realized to be independent form each other through the isolation structure 141, different groups of the sub-pixels may be provided with independent common voltage by the display driver integrated circuit 200. Thus, the common voltage can be configured more flexibly for the sub-pixels of different materials, thereby reducing overall energy consumption of the display module.

In a possible implementation, among the plurality of isolation structures 141, isolation structures 141, corresponding to pixel openings where light-emitting material layers 151 of at least two different light-emitting colors are located, belong to different groups. For example, the display module may include sub-pixels of red (R), green (G), and blue (B), and the isolation structures 141 corresponding to the sub-pixels of different colors are located in different groups. Therefore, the display driver integrated circuit 200 may provide relatively independent common voltages for the sub-pixels of different colors, thereby adapting to different common voltages required by the sub-pixels of different colors due to the materials of the light-emitting material layer 151, and reducing power waste caused by a unified common voltage provided.

In a possible implementation, in different situations, the connection wire connecting the isolation structures 141 may be located in different layers.

In an embodiment, the display panel 100 may further include a first connection wire 401 disposed on a same layer as the isolation structure 141, and the isolation structures 141 in a same group are connected to each other or connected to the display driver integrated circuit 200 through the first connection wire 401.

For example, referring back to FIG. 2 and FIG. 3, FIG. 2 is a cross-sectional view along A-A shown in FIG. 3. When the isolation structures 141 disposed with intervals are formed, the first connection wire 401 may be formed between adjacent isolation structures 141 in the same layer as the isolation structure 141. The first connection wire 401 may extend between the isolation structures 141 to connect the isolation structures 141 in the same group or connect the isolation structure 141 to the display driver integrated circuit 200.

In another example, the display panel 100 may further include a second connection wire 402 disposed on a same layer as the first electrode 120, and the isolation structures 141 are connected to each other or connected to the display driver integrated circuit 200 through the second connection wire 402.

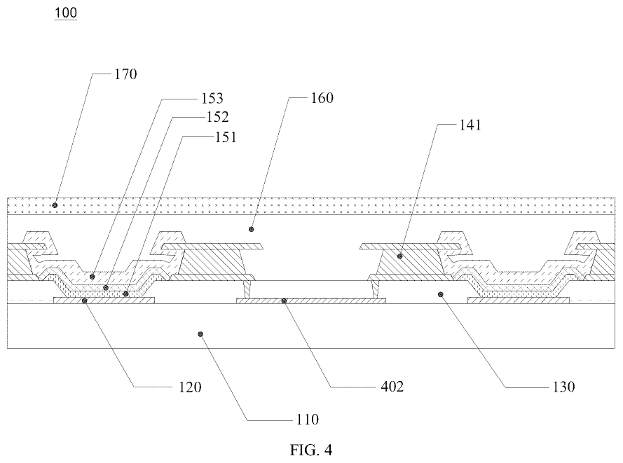

For example, referring to FIG. 4, when the first electrode 120 disposed with intervals are formed, the second connection wire 402 may be formed between adjacent first electrodes 120 in the same layer as the first electrode 120. The second connection wire 402 may extend between the first electrodes 120, and the isolation structure 141 may be electrically connected to the second connection line 402 through a through-hole penetrating through the pixel defining layer 130, so that the second connection wire 402 may connect the isolation structures 141 in the same group or connect the isolation structure 141 to the display driver integrated circuit 200.

In still another example, the display panel 100 may further include a third connection wire 403 located on the array substrate 110. The isolation structures 141 are connected to each other or connected to the display driver integrated circuit 200 through the third connection wire 403.

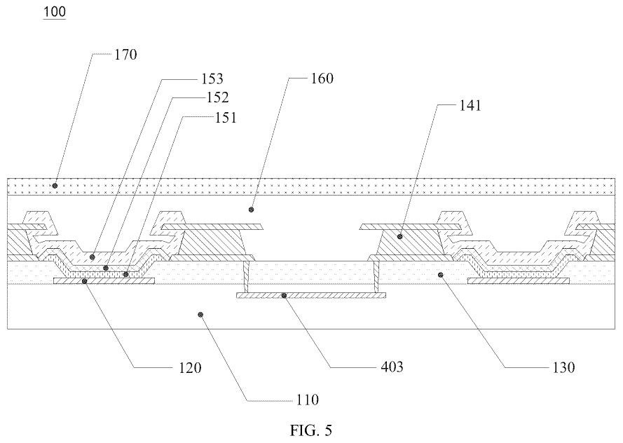

For example, referring to FIG. 5, the array substrate 110 may include a plurality of metal wiring layers, and the third connection wire 403 may be located in one or more metal wiring layers. The isolation structure 141 may be connected to the third connection wire 403 through a through-hole penetrating through the pixel defining layer 130 and at least a part of a planarization layer or an insulation layer in the array substrate 110, so that the isolation structures 141 in a same group may be connected to each other through the third connection wire 403 or the isolation structures 141 may be connected to the display driver integrated circuit 200 through the third connection wire 403.

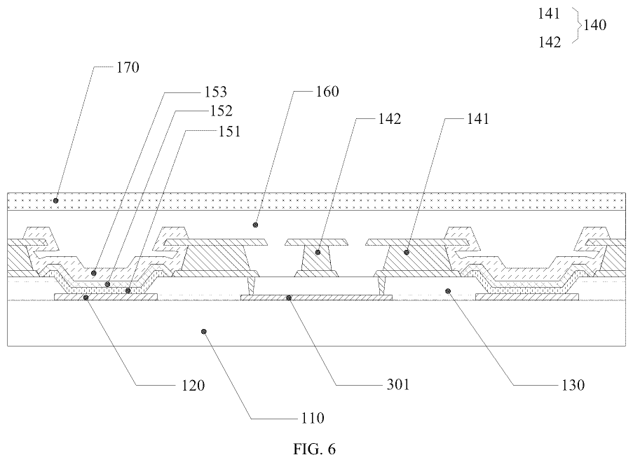

In this embodiment, the display panel 100 may have one or more of the first connection wire 401, the second connection wire 402, and the third connection wire 403 at the same time. For example, referring to FIG. 6, various connection wires may cooperate with each other to form a bridging structure, thereby avoiding cross short circuiting of connection wires in the same layer.

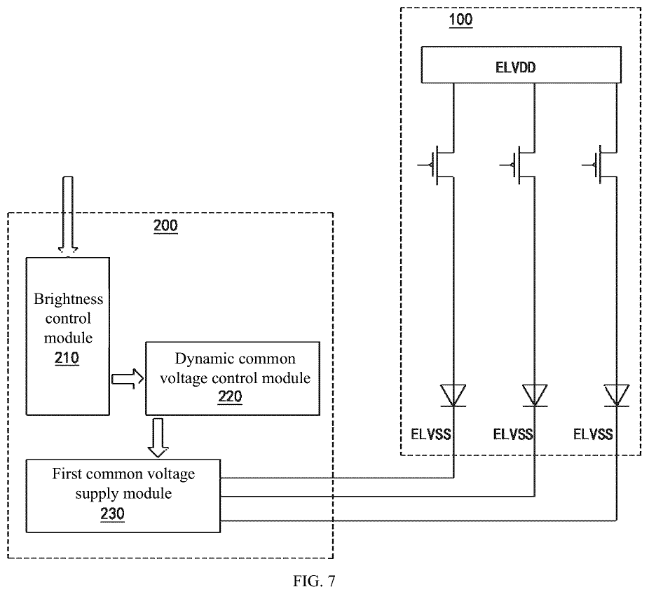

In a possible implementation, referring to FIG. 7, the display driver integrated circuit 200 may include a brightness control module 210, a dynamic common voltage control module 220, and a first common voltage supply module 230.

The brightness control module 210 is configured to receive a display brightness value command, determine at least two common voltage values based on the display brightness value command, and send the at least two common voltage values to the dynamic common voltage control module 220.

The dynamic common voltage control module 220 is respectively connected to the brightness control module 210 and the first common voltage supply module 230, and at least two different groups of the isolation structures 141 are respectively connected to the first common voltage supply module 230. The dynamic common voltage control module 220 is configured to control, based on the at least two common voltage values, the first common voltage supply module 230 to generate at least two independent common voltages, which are respectively provided to different groups of the isolation structures 141.

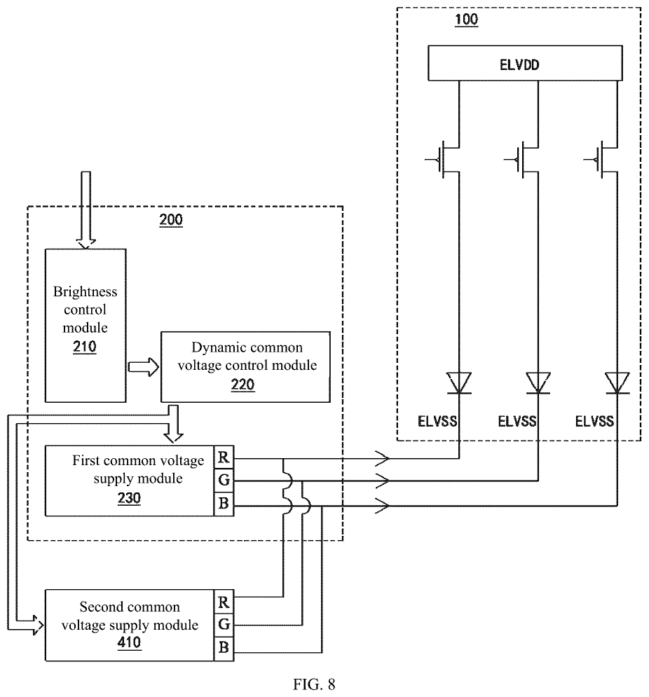

Furthermore, referring to FIG. 8, the display module may further include a second common voltage supply module 410 operating independently of the display driver integrated circuit 200. The second common voltage supply module 410 is connected to the brightness control module 210, and at least two different groups of the isolation structures 141 are respectively connected to the second common voltage supply module 410. The display module includes a first operating mode and a second operating mode.

In the first operating mode, the dynamic common voltage control module 220 is configured to control, based on the at least two common voltage values, the first common voltage supply module 230 to generate at least two independent common voltage respectively provided to different groups of the isolation structures 141.

In the second operating mode, the dynamic common voltage control module 220 is configured to control, based on the at least two common voltage values, the second common voltage supply module 410 to generate at least two independent common voltages, which are respectively provided to different groups of the isolation structures 141.

The first common voltage supply module 230 may be a common voltage supply module integrated within the display driver integrated circuit 200, and the second common voltage supply module 410 may be an external common voltage supply module independent of the display driver integrated circuit 200. For example, the second common voltage supply module 410 may be a power integrated circuit (Power IC) or a module in a power integrated circuit.

The first operating mode may be a low-power mode. For example, the first operating mode may be an always-on display (AOD) mode, also known as off-screen display mode; and the second operating mode may be a normal display mode.

The first common voltage supply module 230 may provide an internal supply common voltage for different groups of the isolation structures 141 in the first operating mode. And the second common voltage supply module 410 may provide internal supply common voltage for different groups of the isolation structures 141 in the second operating mode.

Furthermore, in a possible implementation, a mapping correspondence between the display brightness value and the common voltage value, or a mapping correspondence between the display brightness value and the initialization voltage value may be stored in the brightness control module 210.

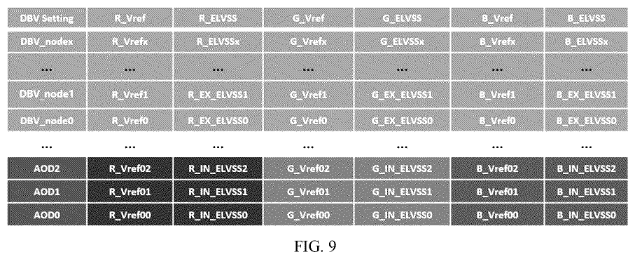

For example, referring to FIG. 9, for each display brightness value (DBVynode or AOD), the mapping correspondence records the common voltage values (R_ELVSS, G_ELVSS, and B_ELVSS) or initialization voltage values (R_Vref, G_Vref, and B_Vref) corresponding to the sub-pixels of three colors under that display brightness value.

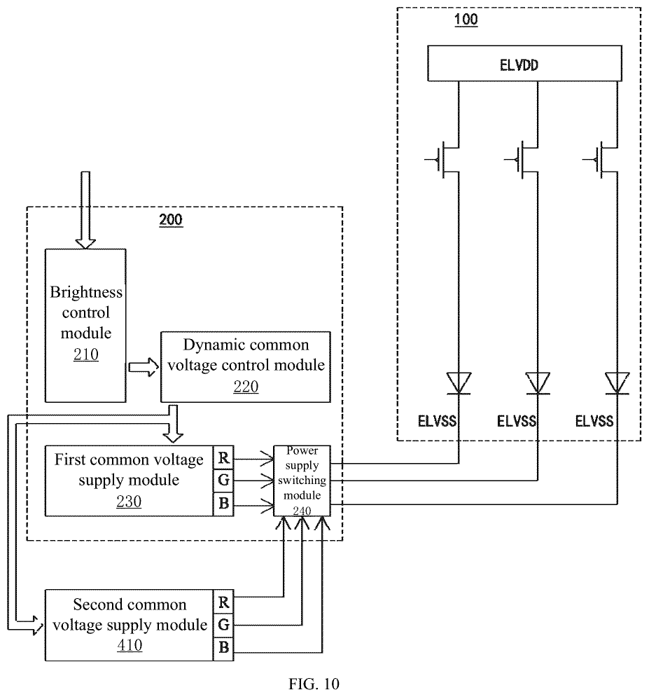

Furthermore, referring to FIG. 10, in a possible implementation, the display driver integrated circuit 200 may further include a power supply switching module 240. The power supply switching module 240 is configured to determine that a common voltage is provided by the first common voltage supply module 230 for each group of the isolation structures 141 in the first operating mode; or a common voltage is provided by the second common voltage supply module 410 for each group of the isolation structures 141 in the second operating mode.

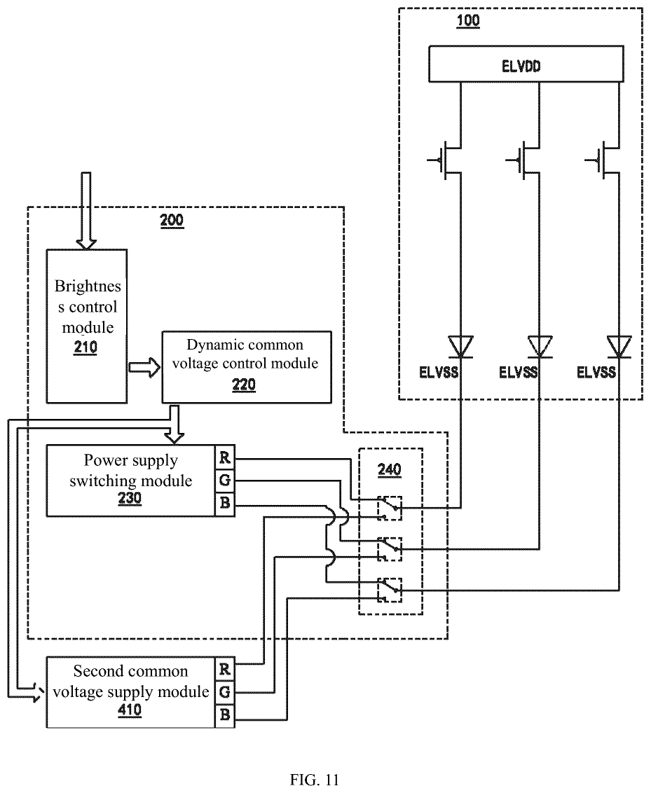

For example, referring to FIG. 11, the power supply switching module 240 may include a switch key respectively corresponding to each group of the isolation structures 141, the switch key is configured to select the first common voltage supply module 230 or the second common voltage supply module 410 to provide a voltage output to the group of the isolation structures 141.

In a possible implementation, the array substrate 110 may include a plurality of pixel driving circuits. The plurality of pixel driving circuits are divided into at least two groups. For example, pixel driving circuits corresponding to sub-pixels of different colors may be divided into different groups.

Optionally, in this embodiment, a group of the pixel driving circuits corresponds to a group of the isolation structures 141.

The display driver integrated circuit 200 is further connected to each group of the pixel driving circuits respectively. The display driver integrated circuit 200 is configured to provide, based on the display brightness value command received, independent initialization voltage for each group of the pixel driving circuits.

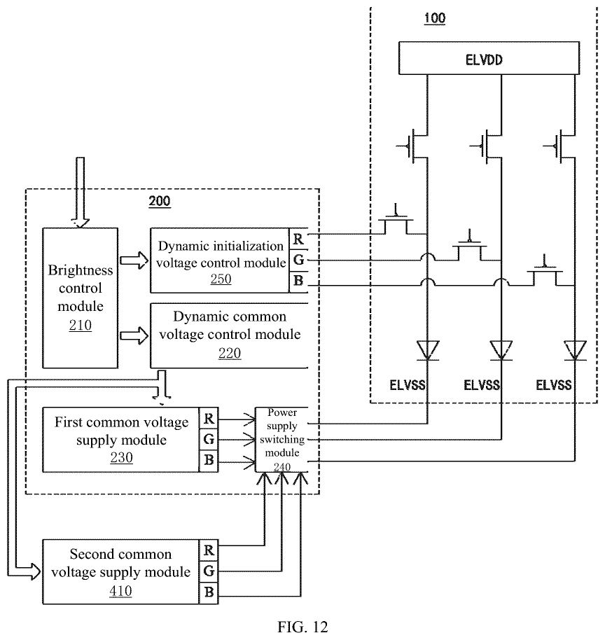

For example, referring to FIG. 12, the display driver integrated circuit 200 may further include a dynamic initialization voltage control module 250 connected to the brightness control module 210. The brightness control module 210 is configured to receive a display brightness value command, determine at least two initialization voltage values based on the display brightness value command, and send the at least two initialization voltage values to the dynamic initialization voltage control module 250.

At least two different groups of the pixel driving circuits are respectively connected to the dynamic initialization voltage control module 250. The dynamic initialization voltage control module 250 is configured to generate at least two independent initialization voltages (Vref) based on at least two initialization voltage values, and respectively provide the at least two initialization voltage values to different groups of the pixel driving circuits.

Therefore, according to the display module provided by the embodiment, the initialization voltage may be provided relatively independently for different groups of the sub-pixels, thereby solving a problem that contrast and response indicators (such as dragging) of sub-pixels of different colors cannot be balanced under low brightness.

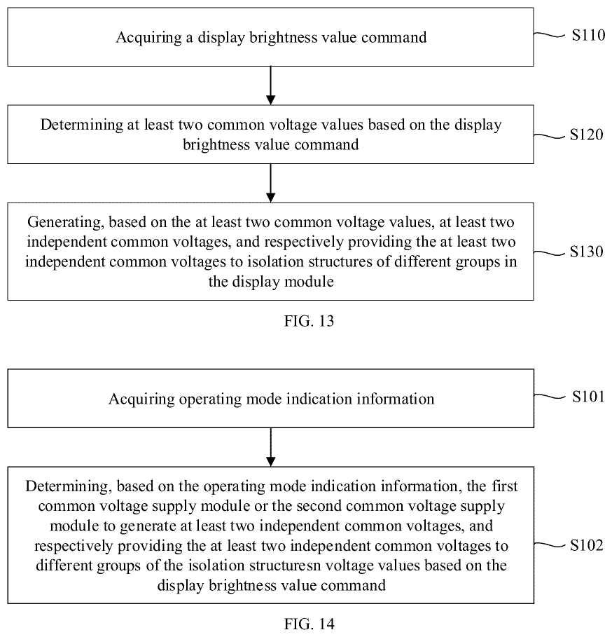

Referring to FIG. 13, a control method for a display module is provided in this embodiment, and the method includes the following steps.

Step S110: acquiring a display brightness value command.

Step S120: determining at least two common voltage values based on the display brightness value command.

Step S130: generating, based on the at least two common voltage values, at least two independent common voltages, and respectively providing the at least two independent common voltages to isolation structures of different groups in the display module.

Thus, the sub-pixels with different materials may be provided with a common voltage more flexibly, thereby reducing overall energy consumption of the display module.

Furthermore, in some possible implementations, as shown in FIGS. 10 to 12, the display driver integrated circuit may include a first common voltage supply module, and the display module further includes a second common voltage supply module operating independently of the display driver integrated circuit. On this basis, referring to FIG. 14, the method provided in this embodiment may include the following steps before step S110.

Step S101: acquiring operating mode indication information.

In this embodiment, the operating mode indication information may be configured to indicate the display module provided in this embodiment to operate in a low-power mode or in a normal display mode.

Step S102: determining, based on the operating mode indication information, the first common voltage supply module or the second common voltage supply module to generate at least two independent common voltages, and respectively providing the at least two independent common voltages to different groups of the isolation structures.

In this embodiment, one of the first common voltage supply module and the second common voltage supply module may be selected, based on the different operating modes, to generate at least two independent common voltages respectively provided to different groups of the isolation structures.

For example, in the low-power mode, the first common voltage supply module is selected to generate at least two independent common voltages respectively provided to different groups of the isolation structures. In the normal display mode, the second common voltage supply module is selected to generate at least two independent common voltages respectively provided to different groups of the isolation structures.

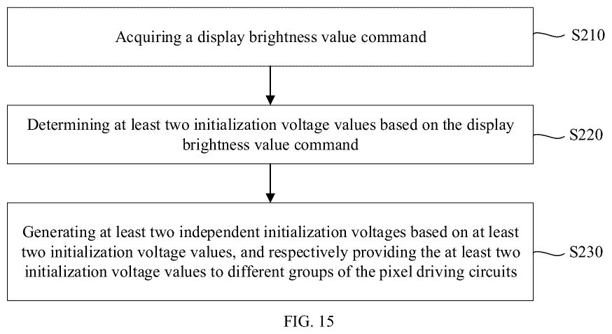

Furthermore, in some possible implementations, the array substrate may include a plurality of pixel driving circuits. The plurality of pixel driving circuits are divided into at least two groups. On this basis, referring to FIG. 15, the control method for the display module provided in this embodiment may further include the following steps.

Step S210: acquiring a display brightness value command.

Step S220: determining at least two initialization voltage values based on the display brightness value command.

Step S230: generating at least two independent initialization voltages based on at least two initialization voltage values, and respectively providing the at least two initialization voltage values to different groups of the pixel driving circuits.

Thus, according to the display module provided by the embodiment, the initialization voltage may be provided relatively independently for different groups of the sub-pixels, thereby solving a problem that contrast and response indicators (such as dragging) of sub-pixels of different colors cannot be balanced under low brightness.

Another display module is further provided by the present disclosure. The display module includes a display driver integrated circuit and a display panel. And the display panel includes an array substrate, and a plurality of pixel units located on a side of the array substrate.

The plurality of pixel units are divided into at least two groups, the display driver integrated circuit is connected to each group of the pixel units respectively. The display driver integrated circuit is configured to provide independent common voltage for each group of the pixel units based on a display brightness value command received.

For example, in addition to the isolation structure provided in the embodiment mentioned above, other methods may also be used in this embodiment to enable different groups of the pixel units to have relatively independent common voltage supply circuits.

On this basis, similar to the embodiment mentioned above, the display driver integrated circuit may be configured to provide an independent common voltage for each group of the pixel units based on the display brightness value command received. Thus, the sub-pixels with different materials may be provided with a common voltage more flexibly, thereby reducing overall energy consumption of the display module.

In some possible implementations, the pixel unit may include a first electrode, a light-emitting material layer, and a second electrode stacked in sequence. The first electrode is connected to a pixel driving circuit in the array substrate, and the second electrode is connected to the display driver integrated circuit.

For example, in this embodiment, a layer where the second electrode is located may be patterned through evaporation cooperated with a mask plate, so that the second electrodes of different pixel units may be independent from each other, and the second electrodes of a same group of the pixel units may be connected directly to each other or connected to each other through other connection wires. Alternatively, the second electrodes of different pixel units may be independent from each other, and each second electrode may be connected to the display driver integrated circuit. Thus, the pixel driving circuit may provide independent common voltage for different groups of the pixel units, or provide independent common voltage for each pixel unit based on grouping.

In some possible implementations, the color of light emitted from the light-emitting material layers of a same group of the pixel units is the same, and the color of light emitted from the light-emitting material layers of different groups of the pixel units is different. Thus, the display driver integrated circuit may provide relatively independent common voltages for pixel units with different colors, thereby adapting to different common voltages required by the sub-pixels of different colors due to the materials of the light-emitting material layer, and reducing power waste caused by a unified common voltage provided.

In some possible implementations, the display driver integrated circuit includes a brightness control module, a dynamic common voltage control module, and a first common voltage supply module.

The brightness control module is configured to receive the display brightness value command, determine at least two common voltage values based on the display brightness value command, and send the at least two common voltage values to the dynamic common voltage control module.

The dynamic common voltage control module is respectively connected to the brightness control module and the first common voltage supply module, and at least two different groups of the pixel units are respectively connected to the first common voltage supply module. The dynamic common voltage control module is configured to control, based on the at least two common voltage values, the first common voltage supply module to generate at least two independent common voltages respectively provided to different groups of the pixel units

In some possible implementations, the display module may further include a second common voltage supply module operating independently of the display driver integrated circuit. The second common voltage supply module is connected to the brightness control module, and at least two different groups of the pixel units are respectively connected to the second common voltage supply module.

The display module includes a first operating mode and a second operating mode.

In the first operating mode, the dynamic common voltage control module is configured to control, based on the at least two common voltage values, the first common voltage supply module to generate at least two independent common voltages respectively provided to different groups of the pixel units.

In the second operating mode, the dynamic common voltage control module is configured to control, based on the at least two common voltage values, the second common voltage supply module to generate at least two independent common voltages respectively provided to different groups of the pixel units.

In some possible implementations, the display driver integrated circuit further includes a power supply switching module. The power supply switching module is configured to determine that a common voltage is provided by the first common voltage supply module for each group of the pixel units in the first operating mode, or a common voltage is provided by the second common voltage supply module for each group of the pixel units in the second operating mode.

In some possible implementations, the array substrate includes a plurality of pixel driving circuits. The plurality of pixel driving circuits are divided into at least two groups.

the display driver integrated circuit is further connected to each group of the pixel driving circuits respectively. The display driver integrated circuit is configured to provide, based on the display brightness value command received, independent initialization voltage for each group of the pixel driving circuits for initializing the first electrode.

In some possible implementations, a group of the pixel driving circuits corresponds to a group of the pixel units.

In some possible implementations, the display driver integrated circuit may further include a dynamic initialization voltage control module connected to the brightness control module. The brightness control module is configured to receive the display brightness value command, determine at least two initialization voltage values based on the display brightness value command, and send the at least two initialization voltage values to the dynamic initialization voltage control module.

At least two different groups of the pixel driving circuits are respectively connected to the dynamic initialization voltage control module. The dynamic initialization voltage control module is configured to generate at least two independent initialization voltages based on at least two initialization voltage values, and respectively provide the at least two initialization voltage values to different groups of the pixel driving circuits.

That is to say, in this embodiment, the display driver integrated circuit may adopt the same or similar construction and working principle as the display driver integrated circuit shown in FIGS. 7 to 12 of the embodiment mentioned above, and details are not described herein again.

An electronic device is further provided by the present disclosure. The electronic device includes the display module provided in the present disclosure. The electronic device may include a mobile phone, a tablet, a smart wearable device, a television, a laptop, a monitor, and other devices with display and touch functions.

In some possible implementations, the electronic device further includes an interaction module or an ambient light detection module; the interaction module is configured to generate display brightness value command in response to user operation, and the ambient light detection module is configured to detect the ambient light intensity and generating corresponding display brightness value command.

For example, the electronic device may generate the display brightness value command by accepting user operations or automatically sensing ambient light and send it to the display module. The display module may provide different common voltages or reference voltages for different groups of sub-pixels based on the display brightness value command.

In conclusion, a display module, a control method for a display module, and an electronic device are provided in the present disclosure. In a case where the common electrode of each sub-pixel is independent by setting isolation structures, the display driver integrated circuit provides independent common voltage for different groups of the sub-pixels. Thus, the common voltage may be configured more flexibly for the sub-pixels of different materials, thereby reducing overall energy consumption of the display module.

Each technical feature in the above embodiments may be combined in any way, and to simplify the description, not all possible combinations of the technical features in the above embodiments have been described. However, as long as there is no contradiction in the combination of these technical features, it should be considered as within the scope of this specification.

What is claimed is:

1. A display module, comprising a display driver integrated circuit and a display panel, wherein
the display panel comprises:
an array substrate; and
a plurality of isolation structures located on a side of the array substrate, wherein the isolation structure is conductive; and the plurality of isolation structures are divided into at least two groups, the isolation structures in a same group are electrically connected to each other, and the isolation structures in different groups are electrically isolated from each other;
the display driver integrated circuit is connected to each group of the isolation structures respectively, and the display driver integrated circuit is configured to provide independent common voltage for each group of the isolation structures based on a display brightness value command received.

2. The display module according to claim 1, wherein the display panel further comprises:
a pixel defining layer located between the array substrate and the plurality of isolation structures; the pixel defining layer comprises a plurality of pixel openings, an isolation opening is formed in the isolation structure, and an orthographic projection of the pixel opening on the array substrate is within an orthographic projection of the isolation opening on the array substrate.

3. The display module according to claim 2, wherein the display panel further comprises:
a plurality of first electrodes disposed with intervals;
the array substrate comprises a pixel driving circuit; wherein the first electrode is connected to the pixel driving circuit in the array substrate; the pixel defining layer is located on a side, away from the array substrate, of the first electrode, and the pixel opening exposes the first electrode; and
a light-emitting material layer and a second electrode stacked in sequence are disposed in the pixel opening; and the second electrode extends from the pixel opening to be in electrical contact with the isolation structure.

4. The display module according to claim 3, wherein the display panel further comprises a first inorganic encapsulation layer located on a side, away from the array substrate, of the second electrode.

5. The display module according to claim 4, wherein at least a part of the first inorganic encapsulation layer extends, along a sidewall of the isolation structure facing the isolation opening, from an inner edge of the pixel opening to a side, away from the array substrate, of the isolation structure.

6. The display module according to claim 3, wherein at least two isolation structures of the plurality of isolation structures, respectively corresponding to pixel openings with light-emitting material layers emitting light of different colors, are located in different groups.

7. The display module according to claim 3, wherein the display panel further comprises a first connection wire disposed in a same layer as the plurality of isolation structures, and the isolation structures in the same group are connected to each other or connected to the display driver integrated circuit through the first connection wire; or
the display panel further comprises a second connection wire disposed in a same layer as the first electrode, and the isolation structures in the same group are connected to each other or connected to the display driver integrated circuit through the second connection wire; or
the display panel further comprises a third connection wire disposed in the array substrate, and the isolation structures in the same group are connected to each other or connected to the display driver integrated circuit through the third connection wire.

8. The display module according to claim 1, wherein the display driver integrated circuit comprises a brightness control module, a dynamic common voltage control module, and a first common voltage supply module;
the brightness control module is configured to receive the display brightness value command, determine at least two common voltage values based on the display brightness value command, and send the at least two common voltage values to the dynamic common voltage control module;
the dynamic common voltage control module is respectively connected to the brightness control module and the first common voltage supply module, and at least two different groups of the isolation structures are respectively connected to the first common voltage supply module; and the dynamic common voltage control module is configured to control, based on the at least two common voltage values, the first common voltage supply module to generate at least two independent common voltages respectively provided to different groups of the isolation structures.

9. The display module according to claim 8, further comprising a second common voltage supply module operating independently of the display driver integrated circuit, wherein the second common voltage supply module is connected to the brightness control module, and at least two different groups of the isolation structures are respectively connected to the second common voltage supply module;
the display module comprises a first operating mode and a second operating mode;
in the first operating mode, the dynamic common voltage control module is configured to control, based on the at least two common voltage values, the first common voltage supply module to generate at least two independent common voltages respectively provided to different groups of the isolation structures; and
in the second operating mode, the dynamic common voltage control module is configured to control, based on the at least two common voltage values, the second common voltage supply module to generate at least two independent common voltage respectively provided to different groups of the isolation structures.

10. The display module according to claim 8, wherein the display driver integrated circuit further comprises a power supply switching module, and the power supply switching module is configured to determine to provide a common voltage by the first common voltage supply module for each group of the isolation structures in the first operating mode, or provide a common voltage by the second common voltage supply module for each group of the isolation structures in the second operating mode.

11. The display module according to claim 3, wherein the pixel driving circuit is divided into at least two groups of pixel driving circuits; and
the display driver integrated circuit is further respectively connected to each group of the pixel driving circuits, and the display driver integrated circuit is configured to provide, based on the display brightness value command received, independent initialization voltage for each group of the pixel driving circuits for initializing the first electrode.

12. The display module according to claim 11, wherein the display driver integrated circuit further comprises a dynamic initialization voltage control module connected to the brightness control module; and the brightness control module is configured to receive the display brightness value command, determine at least two initialization voltage values based on the display brightness value command, and send the at least two initialization voltage values to the dynamic initialization voltage control module; and
at least two different groups of the pixel driving circuits are respectively connected to the dynamic initialization voltage control module; the dynamic initialization voltage control module is configured to generate at least two independent initialization voltages based on at least two initialization voltage values, and respectively provide the at least two initialization voltage values to different groups of the pixel driving circuits.

13. A control method for a display module, applied to the display module according to claim 1, comprising:
acquiring a display brightness value command;
determining at least two common voltage values based on the display brightness value command; and
generating, based on the at least two common voltage values, at least two independent common voltages, and providing the at least two independent common voltages to isolation structures of different groups in the display module respectively.

14. The control method according to claim 13, wherein the display driver integrated circuit comprises a first common voltage supply module, and the display module further comprises a second common voltage supply module operating independently of the display driver integrated circuit; and
the method further comprises:
acquiring operating mode indication information;
determining, based on the operating mode indication information, the first common voltage supply module or the second common voltage supply module to generate at least two independent common voltages respectively provided to different groups of the isolation structures.

15. The control method according to claim 13, wherein the array substrate comprises a plurality of pixel driving circuits, and the plurality of pixel driving circuits are divided into at least two groups; and the method further comprises:
acquiring a display brightness value command;
determining at least two initialization voltage values based on the display brightness value command; and
generating at least two independent initialization voltages based on at least two initialization voltage values, and respectively providing the at least two initialization voltage values to different groups of the pixel driving circuits.

16. A display module, comprising a display driver integrated circuit and a display panel, wherein
the display panel comprises:
an array substrate; and
a plurality of pixel units located on a side of the array substrate, wherein the plurality of pixel units are divided into at least two groups, the display driver integrated circuit is connected to each group of the pixel units, and the display driver integrated circuit is configured to provide independent common voltage for each group of the pixel units based on a display brightness value command received.

17. The display module according to claim 16, wherein the pixel unit comprises a first electrode, a light-emitting material layer, and a second electrode stacked in sequence, the array substrate comprises a pixel driving circuit, the first electrode is connected to the pixel driving circuit in the array substrate, and the second electrode is connected to the display driver integrated circuit;
light-emitting material layers of the pixel units in a same group have a same light-emitting color, and light-emitting material layers of the pixel units in different groups have different light-emitting colors.

18. The display module according to claim 17, wherein the display driver integrated circuit comprises a brightness control module, a dynamic common voltage control module, and a first common voltage supply module;
the brightness control module is configured to receive the display brightness value command, determine at least two common voltage values based on the display brightness value command, and send the at least two common voltage values to the dynamic common voltage control module; and
the dynamic common voltage control module is respectively connected to the brightness control module and the first common voltage supply module, and at least two different groups of the pixel units are respectively connected to the first common voltage supply module; and
the dynamic common voltage control module is configured to control, based on the at least two common voltage values, the first common voltage supply module to generate at least two independent common voltages respectively provided to different groups of the pixel units.

19. The display module according to claim 18, further comprising a second common voltage supply module operating independently of the display driver integrated circuit, wherein the second common voltage supply module is connected to the brightness control module, and at least two different groups of the pixel units are respectively connected to the second common voltage supply module;
the display module comprises a first operating mode and a second operating mode;
in the first operating mode, the dynamic common voltage control module is configured to control, based on the at least two common voltage values, the first common voltage supply module to generate at least two independent common voltages respectively provided to different groups of the pixel units; and
in the second operating mode, the dynamic common voltage control module is configured to control, based on the at least two common voltage values, the second common voltage supply module to generate at least two independent common voltage respectively provided to different groups of the pixel units.

20. The display module according to claim 19, wherein the display driver integrated circuit further comprises a power supply switching module, and the power supply switching module is configured to determine to provide a common voltage by the first common voltage supply module for each group of the pixel units in the first operating mode, or provide a common voltage by the second common voltage supply module for each group of the pixel units in the second operating mode;
the pixel driving circuit is divided into at least two groups of pixel driving circuits;
the display driver integrated circuit is further respectively connected to each group of the pixel driving circuits, and the display driver integrated circuit is configured to provide, based on the display brightness value command received, independent initialization voltage for each group of the pixel driving circuits for initializing the first electrode;
each group of the pixel driving circuits corresponds to a group of the pixel units;
the display driver integrated circuit further comprises a dynamic initialization voltage control module connected to the brightness control module; and the brightness control module is configured to receive the display brightness value command, determine at least two initialization voltage values based on the display brightness value command, and send the at least two initialization voltage values to the dynamic initialization voltage control module; and
at least two different groups of the pixel driving circuits are respectively connected to the dynamic initialization voltage control module; the dynamic initialization voltage control module is configured to generate at least two independent initialization voltages based on at least two initialization voltage values, and respectively provide the at least two initialization voltage values to different groups of the pixel driving circuits.
